(19) United States
(12) Patent Application Publication
(10) Pub. No.: US 2008/0188061 A1
(43) Pub. Date: Aug. 7, 2008

(54) METHOD OF PROTECTING FRONT SURFACE STRUCTURE OF WAFER AND METHOD OF WAFER DIVIDING

(76) Inventor: Chih-Hsien Chen, Hsin-Chu Hsien (TW)

Correspondence Address: NORTH AMERICA INTELLECTUAL PROPERTY CORPORATION, P.O. BOX 506, MERRIFIELD, VA, 22116, US

(21) Appl. No.: 11/762,036

(22) Filed: Jun. 12, 2007

(30) Foreign Application Priority Data
Feb. 5, 2007 (TW) 096104148

(51) Int. Cl. H01L 21/02

(52) U.S. Cl. 438/464; 257/E21.599

(57) ABSTRACT

A method of protecting front surface structure of a wafer and method of wafer dividing is provided. Initially, a wafer having a plurality of device disposed on a front surface thereof is provided. A protective layer is formed on the front surface of the wafer and a first bonding layer is provided to bond the wafer to a carrier. Subsequently, a wafer dividing process is performed to form a plurality of dies. After that, the first bonding layer and the protective layer are removed to separate the dies individually.

### BACKGROUND OF THE INVENTION

1. Field of the Invention

The present invention relates to a method of protecting a front surface structure of a wafer, and particularly to a method including forming a water-soluble protective layer covering a front surface of a wafer and removing the water-soluble protective layer utilizing hot water after the wafer is divided in order to form a plurality of dies.

2. Description of the Prior Art

Technologies for carrying a wafer are developed for specific processing of ultra-thin wafers and manufacturing of MEMS devices, which are used in various consumer electronic devices. Thousands of electronic circuits, MEMS devices, or optical devices are formed on a wafer and separated to form a plurality of dies for subsequent packaging. Technologies for dividing a wafer are described as follows.

1) In order to increase the mechanical strength of the wafer, wafers intended for segmentation are bonded to a carrier wafer. These wafers are separated by various methods after segmentation. For example:

a) A piece of twin-adhesive tape is used to bond the wafer to the carrier wafer and the twin-adhesive tape is subsequently removed utilizing a specific process to separate the wafers.

b) An adhesive material, such as a glue or wax, is used for directly bonding the wafer to the carrier wafer. After the wafer dividing process, the wafers and the sandwiched adhesive material are immersed in a solvent to remove the adhesive material and therefore the wafer and the carrier wafer are separated.

2) A single-adhesive tape and a frame are used to bond the wafer to the frame for the following wafer dividing process. The single-adhesive tape and the frame are removed after the wafer is divided.

After the tape or the adhesive material used in the abovementioned process is removed, retention is found on the interface between the adhesive material and the wafer or the interface between the single-adhesive tape and the wafer. In particular, retention remains on the surface of the MEMS devices or optical devices disposed on the individual dies. If the retention cannot be removed easily, this results in contamination and poor yield.

### SUMMARY OF THE INVENTION

Accordingly, a method of protecting a front surface structure of a wafer, and a wafer dividing method are disclosed to solve the problem of retention remaining on the surface of the wafer. The product of the present invention has an improved yield and is free from the problem of retention.

A primary objective of the present invention is to provide a method of protecting a front surface structure of a wafer, and a wafer dividing method. Initially, a wafer having a plurality of devices disposed on a front surface thereof is provided. A protective layer is formed to cover the front surface. A first bonding layer is provided to bond the protective layer to a carrier wafer. A wafer dividing process is performed on a back surface of the wafer and a plurality of dies is formed. The first bonding layer and the protective layer are subsequently removed.

In addition, another method of protecting the front surface structure of a wafer and a wafer dividing method are disclosed. A wafer having a plurality of devices on a front surface thereof is provided. A water-soluble protective layer is formed on the front surface of the wafer. A first bonding layer is attached to the protective layer in order to bond the wafer to a carrier wafer. A wafer dividing process is performed to segment the wafer from a back surface of the wafer and separate each device to form a plurality of dies. A second bonding layer is provided and attached to the back surface of the dies. The dies are subsequently reversed. Then, the water-soluble protective layer and the first bonding layer are removed. The second bonding layer is subsequently removed to separate the dies.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-8 are schematic diagrams illustrating a method of protecting the front surface of a wafer and a wafer dividing method according to a preferred embodiment of the present invention.

### DETAILED DESCRIPTION

Hereinafter, preferred embodiments of the present invention will be described with reference to the accompanying drawings, in which components with substantially the same functions are identified by the same reference numeral for the sake of simplicity. It should be noted, however, that the present invention is in no way limited to the following illustrative embodiments.

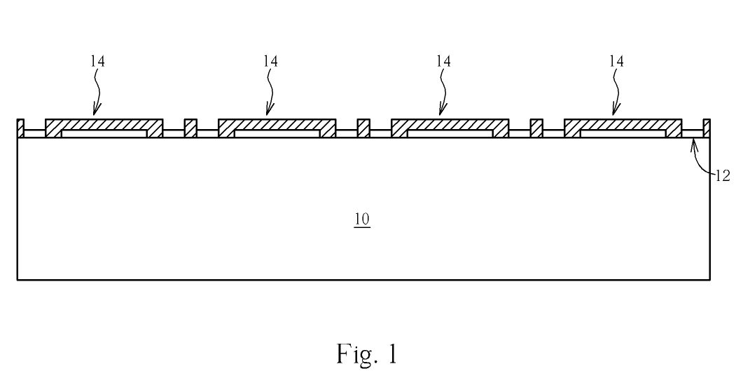

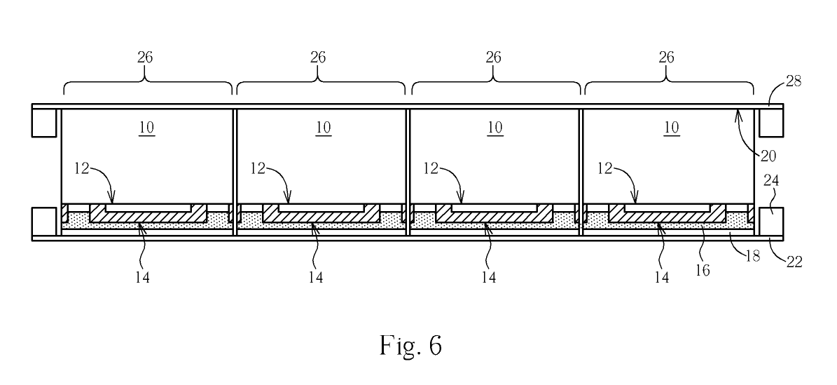

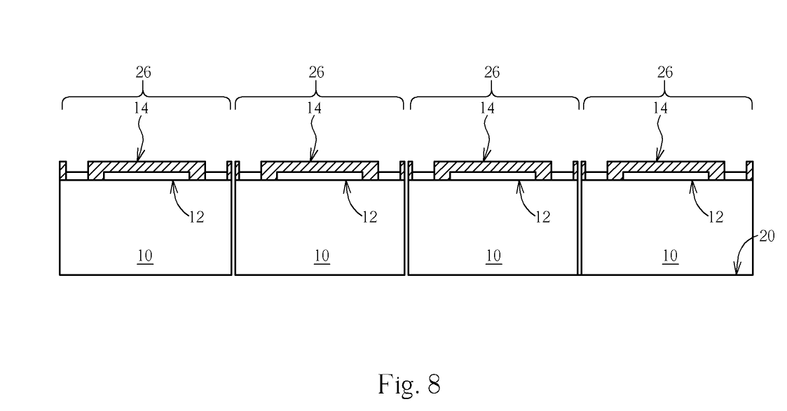

Please refer to FIGS. 1-8. FIGS. 1-8 are schematic diagrams illustrating a method of protecting the front surface structure of a wafer and a wafer dividing method according to a preferred embodiment of the present invention. As shown in FIG. 1, a wafer 10 is provided. Several processes are performed to form a plurality of devices 14 on a front surface 12 of the wafer 10. The devices 14 may include MEMS devices of a 3D structure, optical devices for sensing or projecting images, or electrical circuits for signal transmitting.

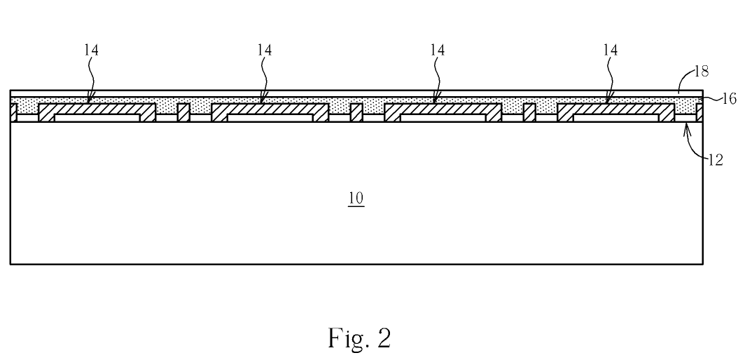

As shown in FIG. 2, a photoresist layer 16 is formed on the front surface 12 of the wafer 10. A protective layer 18 is formed covering the front surface 12 of the wafer 10. The function of the photoresist layer 16 or the protective layer 18 is to protect the devices 14 disposed on the front surface 12 of the wafer 10. The protective layer 18 of the present invention is also capable of protecting the devices 14. The formation of the photoresist layer 16 is not an essential step of the present invention. Consequently, the formation of the photoresist layer 16 is optional depending on the type of the devices 14. For example, when the devices 14 are MEMS devices of a 3D structure, the photoresist layer 16 is formed covering the MEMS devices and filling up the spaces inside the MEMS devices to strengthen the protecting capability of the photoresist layer 16. Moreover, a curing process is performed to make the protective layer 18 lose its adhesive quality. The present embodiment uses a water-soluble glue as the material of the protective layer 18. After the curing process, the cured protective layer 18 cannot be removed by normal-temperature water or solvent. Only hot water of a higher temperature can be used to remove the cured protective layer 18.

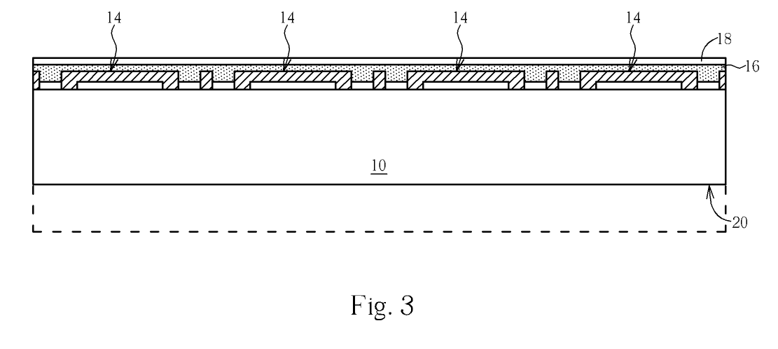

Please refer to FIG. 3. Depending on the type and the thickness of the wafer 10, a thinning process, such as a CMP process, is optionally performed on a back surface 20 of the wafer 10 to reduce the thickness of the wafer 10. If the wafer 10 is a thin wafer, the thinning processes may be omitted. The method of the thinning process is not limited to the CMP process illustrated in the present embodiment. Other methods capable of thinning a wafer or substrate, such as an etching process or a wafer-thinning machine may be used in the present invention.

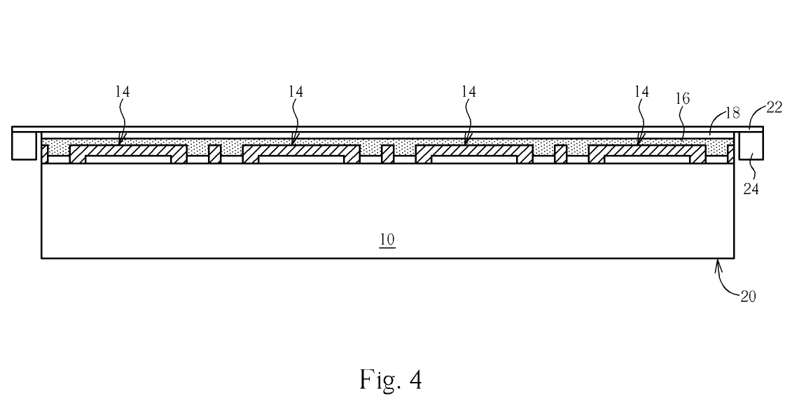

As shown in FIG. 4, a piece of a first bonding layer 22 is provided. The first bonding layer 22 is attached to the protective layer 18, and therefore, the wafer 10 is bonded to a carrier, such as a frame 24 or a carrier wafer (not shown). The first bonding layer 22 includes tapes usually used in the prior art dicing process. The property of the tape will therefore not be detailed in this disclosure.

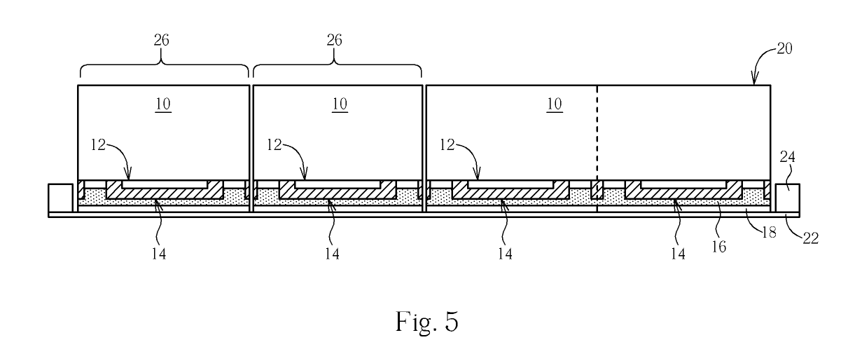

As shown in FIG. 5, a wafer dividing process is performed. A wafer dividing machine (not shown) is used to divide the wafer 10 from a back surface 20 of the wafer 10. The devices 16 are separated individually and a plurality of dies 26 is formed. Since the frame 24 supports the first bonding layer 22, the dies 26 are arranged on the first bonding layer 22. The frame 26 also prevents wrinkling of the first bonding layer 22 and collision of the dies 26. Then, a piece of second bonding layer 28 is provided and is attached to a respective back surface of the dies 26 as shown in FIG. 5. The dies 26 will then be reversed to be up-side down. The method of reversing the dies 26 is not limited to using the second bonding layer 28 shown in the present embodiment. Other methods, such as utilizing a wafer chunk or an electrostatic chunk, may be used in the present invention to reverse the dies 26 without damaging the devices 14.

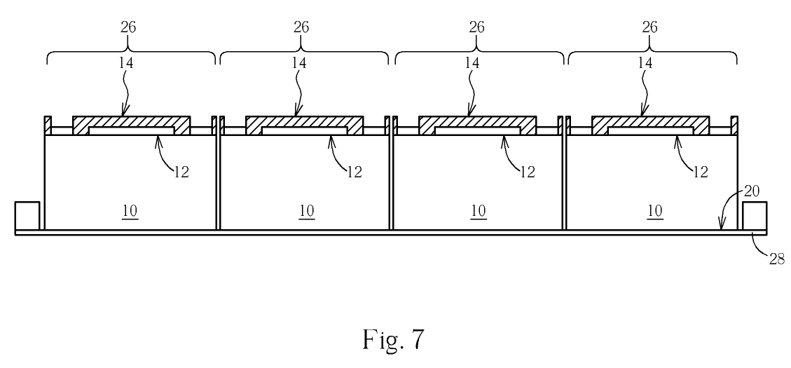

As shown in FIG. 7, the first bonding layer 22 disposed on the protective layer 18 is effectively removed by hot water in a short time period. Afterwards, the second bonding layer 28 is removed to separate the dies 26 individually for the following packaging process.

Accordingly, the feature of the present invention is to utilize the protective layer as an intermediate between the wafer and the first bonding layer. The use of the protective layer has the advantages of protecting the devices from damage, preventing retention on the surface of the wafer, and improving yield of the products. Furthermore, the present invention may be performed on wafers of various thicknesses. Not only can wafers of normal thickness undergo the method of the present invention, but thin wafers may also undergo the method of the present invention without necessitating purchasing wafer dividing machines or wafer cleaning machines for thin wafers. Therefore, production costs are reduced. In addition, the wafer dividing process of the present invention is performed after the devices on the front surface are protected. The application of the present invention is not limited to wafer dividing, and other semiconductor processes requiring protection of front surface devices can also undergo the majority of processes disclosed by the present invention. For example, a double-sided process, which is performed on the back surface of the wafer, may also utilize the protective layer of the present invention to protect the devices on the front surface of the wafer and subsequently perform the double-sided process on the back surface thereof. Therefore, the yield of the product is improved.

Those skilled in the art will readily observe that numerous modifications and alterations of the device and method may be made while retaining the teachings of the invention.

What is claimed is:

1. A method of protecting a front surface structure, comprising:
providing a wafer having a plurality of devices disposed on a front surface thereof;
forming a protective layer covering the front surface;
providing a first bonding layer and attaching the first bonding layer to the protective layer to bond the wafer to a carrier;
performing a wafer dividing process on a back surface of the wafer to form a plurality of dies; and
removing the first bonding layer and the protective layer.

2. The method of claim 1, wherein a photoresist layer is optionally formed to protect the devices on the front surface before the protective layer is formed on the front surface of the wafer.

3. The method of claim 1 further comprising performing a curing process after the protective layer is formed.

4. The method of claim 1, wherein a wafer thinning process is optionally performed on the back surface of the wafer after the wafer is bonded to the carrier.

5. The method of claim 1, further comprising:
providing a second bonding layer; and
attaching the second bonding layer to the back surface of the dies for reversing the dies after the wafer dividing process is performed.

6. The method of claim 1, wherein the protective layer is a water-soluble glue.

7. The method of claim 6, wherein the protective layer is removed by hot water.

8. A method of protecting a front surface structure and wafer dividing, comprising:
providing a wafer having a plurality of devices on a front surface thereof;
forming a water-soluble protective layer on the front surface of the wafer;
providing a first bonding layer and attaching the first bonding layer to the protective layer to bond the wafer to a carrier;
performing a wafer dividing process to segment the wafer from a back surface of the wafer and separate each device to form a plurality of dies;
providing a second bonding layer and attaching the second bonding layer to the back surface of the dies and reversing the dies;
removing the water-soluble protective layer and the first bonding layer; and
removing the second bonding layer to separate the dies.

9. The method of claim 8, wherein a photoresist layer is optionally formed for protecting the devices on the front surface before the water-soluble protective layer is formed on the front surface of the wafer.

10. The method of claim 8 further comprising performing a curing process after the protective layer is formed.

11. The method of claim 8, wherein a wafer thinning process is optionally performed on the back surface of the wafer after the wafer is bonded to the carrier.

12. The method of claim 8, wherein the protective layer is removed by hot water.
